(19) United States
(12) Patent Application Publication
(10) Pub. No.: US 2004/0246030 A1
(43) Pub. Date: Dec. 9, 2004

(54) Speeded up multistage comparator with power reduction and reliable output

(76) Inventor: Steven Jyh-Ren Yang, Hsinchu (TW)

Correspondence Address: Kenton R. Mullins, Stout, Uxa, Buyan & Mullins, LLP, Suite 300, 4 Venture, Irvine, CA, 92618, US

(21) Appl. No.: 10/456,828

(22) Filed: Jun. 6, 2003

(51) Int. Cl. H03K 5/153; G01R 19/00

(52) U.S. Cl. 327/58

(57) ABSTRACT

A configuration of sub-comparators for use within an analog to digital conversion circuit is disclosed. A number of the sub-comparators are adapted to receive equalization and power down control signals. In one embodiment, several of the sub-comparators are cascaded together in the analog to digital conversion circuit. An equalization signal and a power down control signal are applied to at least some of the sub-comparators enabling the sub-comparators to attenuate or eliminate offset voltage and environmental noise associated with the signal to be sampled. Furthermore, in accordance with another aspect, the analog to digital conversion circuit includes a latch type differential sub-comparator, which can attenuate or eliminate output levels of the sub-comparators from residing in an unstable input region of the digital converter.

### BACKGROUND OF THE INVENTION

1. Field of the Invention

The present invention relates generally to semiconductor fabrication and, more particularly, to comparators adapted to cancel offset voltages and reduce power consumption while providing a reliable output.

2. Description of Related Art

Conventional signal processing is typically achieved with the implementation of digital circuits. However, there are many applications that require generation and processing of analog signals. When mixed signal processing is involved, it is a common practice to convert the analog signals to corresponding digital signals for processing by a microprocessor, or the like. Indeed, many microprocessor chips are commercially available with on board analog-to-digital (A/D) converters. The particular type of analog signals utilized in signal processing may require different types of conversion circuits and techniques. For example, various circuits generate analog signals on a single conductor, referenced with respect to ground. This type of signal is known as “single-ended,” meaning that the magnitude of signal is measured with respect to a known reference voltage, such as ground.

Other circuits generate differential analog signals on a pair of conductors. One analog signal on one conductor is measured with respect to the other conductor, and not with respect to a circuit ground. Transformers, differential output amplifiers, as well as many other circuits can generate such types of signals, where it may be desired to use differential as well as single-ended A/D devices.

Generally speaking, A/D device operation is typically based on the use of comparators. A comparator is a circuit that compares two input signals and generates an output signal indicating which of the two signals is, for example, the largest. Since comparators are commonly used in A/D conversion, wherein they convert analog inputs into digital outputs, the prior art presented herein comprises a comparator as a component of an A/D converter, thereby elucidating a typical function of a comparator as a component of a basic A/D converter.

In high-precision applications, a fully differential structure is often applied in a comparator stage to combat environmental common-mode noise such as digital clock cross talk, clock-feed through, power/ground bounce, and 1/f noise. FIG. 1A depicts a conventional comparator circuit 100, which includes four fully differential regenerative sub-comparators 105, 106, 107, and 108 to provide such fully-differential benefits. In addition to these sub-comparators, two sets of single-ended inverting type sub-comparators 162, 164, 166, and 168 are followed to further enhance the signal gain of comparator circuit 100. After all of these sub-comparator stages, two sets of general digital inverters 174, 175, 176 and 173 and a latch 180 are applied to provide a single digital output. Such a multistage comparator possesses a fully-differential and single-ended (FS) structure.

Sub-comparators 105, 106, 107 and 108 are cascaded in separate stages. Sub-comparator 105 receives inputs VinX− and VinX+ from pass circuits 110 and 111, respectively, and provides output signals 121 and 122. The output signals of each stage of the cascaded sub-comparators 105, 106, 107 and 108 are used as the input to the sub-comparators of the next sub-comparator in the cascaded circuit. Sub-comparator 106 receives output signals 121 and 122 from sub-comparator 105 and outputs two signals 123 and 124; sub-comparator 107 receives the output signals 123 and 124 from sub-comparator 106 and outputs two signals 125 and 126; and sub-comparator 108 receives the output signals 125 and 126 from sub-comparator 107 and provides output signals OUT+ and OUT−.

The output signals OUT+ and OUT− from the last sub-comparator 108 in the cascaded circuit are fed into single-ended inverting type sub-comparators 162 and 166, respectively, and then the inverted signals are fed into single-ended inverting type sub-comparators 164 and 168, which further enhances the signal gain. The signals from inverting type sub-comparators 164 and 168 are fed into general digital inverters 174, 176, 175 and 173. The signal from the digital inverter 175 will set or reset latch 180, thus determining the result of the comparison between a differential-negative input signal (analog input signal) Vin−, which is typically input from a source external to the chip, and a differential-positive input signal (analog reference signal) Vin+, which is typically chip-externally injected . The comparison process of these signals generally takes place in two separate steps: a) a sampling phase and b) a bit cycling phase.

With continuing reference to FIG. 1A, circuits 110 and 111 are adapted to provide input signals VinX− and VinX+, which are a signal to be sampled and a reference signal, respectively, to comparator circuit 100. Circuit 110 is used to sample both Vin− and a differential-negative reference signal (analog voltage reference) Vda−, which is typically generated within the chip. Circuit 110 samples Vin− and Vda− at different time intervals. Likewise, circuit 111 operates in the same way as circuit 110 but on both Vin+ and a differential-positive reference signal (analog voltage reference) Vda+, which is typically chip-internally generated. The sequence of delivery of the signal to be sampled (e.g., Vin−) and the reference signal (e.g., Vda−) is determined in accordance with the waveforms Pvin+ and Pda+ depicted in FIG. 1B. The analog signal Vin− (Vin+) is provided to comparator circuit 100 during a period when input control signal Pvin+ is high and Pda+ is low. Analog voltage references Vda− (Vda+) are applied to comparator circuit 100 when Pvin+ goes low a ΔT1 time after switch R6 is closed and after Pda+ becomes high a Δ T3 time after Pvin+ is set low.

Circuit 110 provides Vin− as VinX− during the sampling phase of the A/D conversion process, discussed below. Circuit 110 receives input signal Vin− from a signal source (not shown). When Pvin+ is in “high” state, inverted control signal Pvin− applied to pass circuit 115 of circuit 110 will turn PMOS transistor of pass circuit 115 “on” and Pvin+ applied to pass circuit 115 will turn NMOS transistor of pass circuit 115 “on.” Thus, during the time period when both Pvin+ is in “high” state and Pda+ is in “low” state, both PMOS and NMOS transistors of pass circuit 115 are turned “on” and either transistor provides VinX−=Vin−.

It is important to note that during the time period control signal Pda+ is in “low” state, when Pda+ and Pda− are applied to pass circuit 116 both PMOS and NMOS transistors of pass circuit 116 are turned “off” so that no Vda− signal is delivered to the output of circuit 110. In particular, during this same time period control signal Pda− applied to pass circuit 116 of circuit 110 will turn PMOS transistor “off” and Pda+ applied to NMOS transistor of pass circuit 116 will turn that transistor of pass circuit 116 “off.” Therefore, during the sampling phase Vin− is the output signal from circuit 110 that is applied to comparator circuit 100 for sampling purposes. Similarly, during this sampling phase circuit 111 will output Vin+ to comparator circuit 100. It should be noted that Pvin+ and Pda+ are substantially non-overlapping signals and either Vin− or Vda− can be delivered as an output of circuit 110 at any one time. It is further appreciated that either PMOS transistor or NMOS transistor of pass circuit 115, for example, can provide Vin− as an output of circuit 110; however, the reason for duplication of using both PMOS transistor and NMOS transistor is to ensure the signal quality at the output of circuit 110. For example, in circuit 110 either NMOS transistor or PMOS transistor of pass circuit 115 may be sufficient to deliver input VinX− to comparator circuit 100. However, the reason for duplication and providing both PMOS transistor and NMOS transistor can be to eliminate the possibility of weak signal as one transistor may be weak in delivering high and the other may be weak in delivering low signals. The same rationale can be made for pass circuits 116, 117, and 118. With continuing reference to the timing diagram of FIG. 1B, and following the control signal Pvin+ after the sampling phase is completed, a time delay of Δ T2 occurs after the last sample of input signal is taken, before Pda+ is shifted to a high state. In the illustrated embodiment, the time delay Δ T3 is implemented for example to prevent signal interference at the output of comparator circuit 100.

When control signal Pvin+ is in “low” state, inverted Pvin− applied to pass circuit 117 of circuit 111 will turn PMOS transistor of pass circuit 117 “off” and Pvin+ applied to pass circuit 117 will turn NMOS transistor “off.” During this time period when Pvin+ is low and Pda+ is high, both PMOS and NMOS transistors of pass circuit 118 are turned “on” and either transistor will provide Vda+, which comprises the analog voltage references, as the output of circuit 111. Therefore, during the bit-cycling comparison phase, Vda+ will be the output signal from circuit 111 that is supplied to comparator circuit 100 for comparison purposes. Similarly, circuit 110 will output Vda− to comparator circuit 100 during the bit-cycling phase.

As stated previously, A/D converter conversion takes place in two different phases: a sampling phase and a bit cycling phase. During the sampling phase an analog signal Vin− and Vin+ is applied to circuits 110 and 111, and during the bit-cycling phase analog voltage references Vda− and Vda+ are provided.

Once the signal to be sampled appears at the input to comparator circuit 100 and prior to the initial phase of the sampling period, all of the auto-zeroing signals (i.e., R1, R2, R3, R4, R5 and R6) are set high so that their switches are closed with Vcm common to all, thus maintaining the corresponding sub-comparators at auto-zeroing states. As the sampling phase begins the switches are sequentially opened and balance charges are stored at input nodes of all sub-comparators. When the sampling phase is completed and R6 becomes low, and its corresponding switch is opened, after a delay of Δ T1, Pvin+ is switched to a low state. At this time, the end of the sampling phase, stored charges on the nodes VinT− and VinT+ are proportional to Vin− and Vin+, and also the input offset-voltage of the multistage comparator. If the offset voltage due to differences of potential in different converters in the multistage comparator is neglected, the stored charges at the positive node can be represented with Q+=(Vcm−Vin+)*C and at the negative node Q−=(Vcm−Vin−)*C.

After sampling the analog input, the bit cycling phase is entered, to generate a plurality of bit comparison outputs based on different discrete DC levels (i.e., analog voltage references) at the Vda+ and Vda− terminals. Bit sampling compares the sampled signal with analog voltage references. During the bit cycling phase, referring to FIG. 1B, control signal Pda is “high” and Pvin is “low.” Thus, pass circuit 116 is turned on and pass circuit 115 is turned off. Control signal Pda+ takes “high” and “low” states in accordance with the time sample taken and in accordance with a binary search algorithm which represents the analog signal with a digital word, wherein particulars can be found in Smith and Sedra, 3rd edition (p. 738-746). During this bit-cycling phase, Vda+ and Vda− will appear as stair-like discrete waveforms, and for each stair voltage level for Vda+ and Vda− a corresponding settled voltage level at VinT+ and VinT− terminals exists that can roughly be determined by the equation VinT+=(Q+)/C+Vda+, where Q+ is described above. Then, at these temporarily settled values at both nodes VinT+ and VinT− corresponding comparison outputs are generated at a terminal cmpOut with some delay time wherein the delay time is a function of for example the number of cascaded sub-comparators. The number of the discrete stair values at the Vda+ terminal corresponds for example to the number of comparison outputs/bits at the terminal cmpOut.

FIG. 2 illustrates a prior-art fully differential sub-comparator 200 used in comparator circuit 100. Differential sub-comparator 200 illustrated in FIG. 2 is a symmetrical device, which receives signals IN− and IN+. When input signal IN+ is in low state PMOS transistor 201 is turned “on” and PMOS transistor 203 is turned “off.” Current through PMOS transistor 202, which is operating in saturation mode, will appear at node B and provides a certain voltage Vb. Considering push-pull transistors 205-206, it can be discerned that PMOS transistor 205 is operating in saturation and if Vb is in a high state, OUT+ will be grounded. Similar operation takes place in push-pull transistors 207 and 208, when IN+ is in high state PMOS transistor 203 is turned “on” and Va is formed at node A and the OUT− will be grounded.

In an actual circuit the voltage at node A and the voltage at node B may not be the same and an offset voltage may need to be removed before the next sampling phase. Signals at nodes A and B can have certain environmental noise associated with them. Circuit 200 can attenuate or altogether cancel the noise and provide a voltage gain at its output. The amplified differential voltage output and noise reduction can be shown as: If single-ended gain A is assumed for the gain stage, which consists of 205 and 206 (likewise for 207 and 208 ), then the differential output of sub-comparator=[A(Vin++noise) A(Vin−+noise), thus offsetting the noise and having an amplified differential voltage output of A(2Vin).

It is further appreciated that while sample and hold process is in progress, at every stage of cascaded sub-comparator the output signal associated with that sub-comparator can have a gain relative to the input of that stage and a reduced noise level. Such voltage gain and noise reduction will be repeated at each stage of the cascade and trade off analysis for real estate verses voltage gain and noise reduction should be made. FIG. 3 depicts a conventional inverting type sub-comparator that is controlled by the input signal 301. When input signal 301 is low PMOS transistor 320 is turned “on” and NMOS transistor 310 is turned “off,” and the output is VDD. However, when the input signal is high NMOS transistor 310 is turned “on” and PMOS transistor 320 is turned “off,” and thus the output is VSS There may be no problem in connection with power consumption considerations if a high or low enough input signal appears at input node of inverter (FIG. 3). Otherwise, any other gray-zone signal can simultaneously turn “on” both PMOS 320 and NMOS 310, and thus cause a current leakage between VDD and VSS. Unfortunately, this kind of gray-zone signal will typically appear during comparison developing processes.

Furthermore, since in many consumer products requiring A/D functions time delays exist between different phases whereby power is commensurately consumed during these delays, a need exists to reduce such delay times and/or reduce power consumption during such delay times. Another need exists for such conversion circuits to deliver reliable output. For example, conventional devices may not employ mechanisms to take into consideration unstable input transition regions of normal digital inverters due to process variations.

### SUMMARY OF THE INVENTION

The present invention addresses these needs by providing a fully differential, single-ended inverter and latched differential (FSL) structure. The structure comprises a multistage comparator for performing analog to digital conversion, with the multistage comparator including a plurality of fully differential sub-comparators cascaded in series, a plurality of inverter sub-comparators, a latch type differential sub-comparator, a plurality of inverters, and a latch. A speed of the multistage comparator can be increased during the performance of analog to digital conversion, while power consumption can be reduced and reliability improved. The use of an equalizing control signal and a power down signal in combination with the inventive multistage comparator can, in addition to enhancing speed and conserving power, reduce environmental noise effects.

A method for using a comparator to compare input signals is disclosed in accordance with another aspect of the present invention, the method comprising sampling the input signal and holding the sampled input signal for comparison with a voltage reference signal. An equalization control signal is applied to equalize an offset voltage within the comparator, and a power down control signal is applied to reduce or cut power off to at least one component of the comparator during a time between a sampling phase and a comparison phase. The method also includes providing a falling-edge latch to maintain an output voltage at the falling edge of the falling edge latch. The latch can attenuate or eliminate output levels of sub-comparators of the comparator from residing in an unstable input region of the device.

Any feature or combination of features described herein are included within the scope of the present invention provided that the features included in any such combination are not mutually inconsistent as will be apparent from the context, this specification, and the knowledge of one of ordinary skill in the art. For purposes of summarizing the present invention, certain aspects, advantages and novel features of the present invention have been described herein. Of course, it is to be understood that not necessarily all such aspects, advantages or features will be embodied in any particular embodiment of the present invention. Additional advantages and aspects of the present invention are apparent in the following detailed description and claims.

### BRIEF DESCRIPTION OF THE DRAWINGS

FIG. 1A is a schematic diagram illustrating a prior-art comparator circuit with input offset-voltage cancellation;

FIG. 1B is a schematic diagram illustrating control timing for the comparator circuit of FIG. 1A;

FIG. 2 is a schematic diagram illustrating a conventional fully differential sub-comparator;

FIG. 3 is a schematic diagram illustrating a conventional, single-ended inverting type sub-comparator;

FIG. 4A is a schematic diagram illustrating a performance-improved comparator circuit in accordance with one embodiment of the present invention;

FIG. 4B is a schematic diagram depicting control waveforms for operation of the comparator circuit of FIG. 4A in accordance with one embodiment of the present invention;

FIG. 5 is a schematic diagram illustrating a fully differential sub-comparator with power down and equalizing control in accordance with one embodiment of the present invention;

FIG. 6 is a schematic diagram illustrating a single-ended inverting type sub-comparator with power down control in accordance with one embodiment of the present invention; and

FIG. 7 is a schematic diagram illustrating a latch type differential sub-comparator with enable control signal.

### DETAILED DESCRIPTION OF THE PRESENTLY PREFERRED EMBODIMENTS

Reference will now be made in detail to the presently preferred embodiments of the invention, examples of which are illustrated in the accompanying drawings. Wherever possible, the same or similar reference numbers are used in the drawings and the description to refer to the same or like parts. It should be noted that the drawings are in simplified form and are not to precise scale. In reference to the disclosure herein, for purposes of convenience and clarity only, directional terms, such as, top, bottom, left, right, up, down, over, above, below, beneath, rear and front, are used with respect to the accompanying drawings. Such directional terms should not be construed to limit the scope of the invention in any manner.

Although the disclosure herein refers to certain illustrated embodiments, it is to be understood that these embodiments are presented by way of example and not by way of limitation. The intent of the following detailed description, although discussing exemplary embodiments, is to be construed to cover all modifications, alternatives, and equivalents of the embodiments as may fall within the spirit and scope of the invention as defined by the appended claims. The present invention may be practiced in conjunction with various integrated circuits that are conventionally used in the art, and only so much of the commonly practiced steps are included herein as are necessary to provide an understanding of the present invention. The present invention has applicability in the field of circuits in general. For illustrative purposes, however, the following description pertains to an apparatus and method for improving signal comparison in a fully differential, single-ended inverter and latched differential architecture.

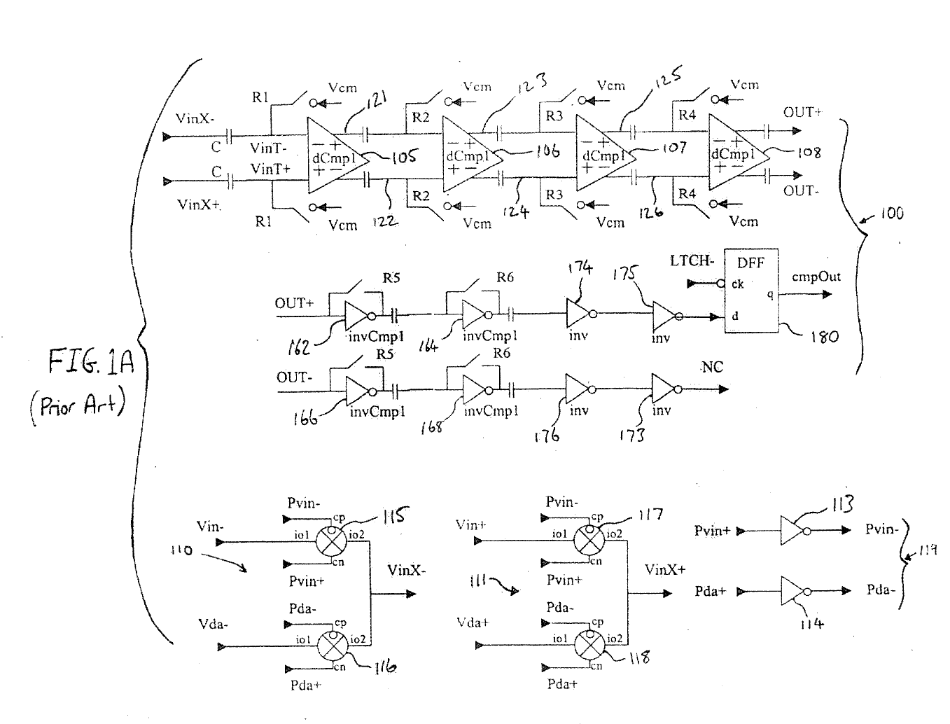

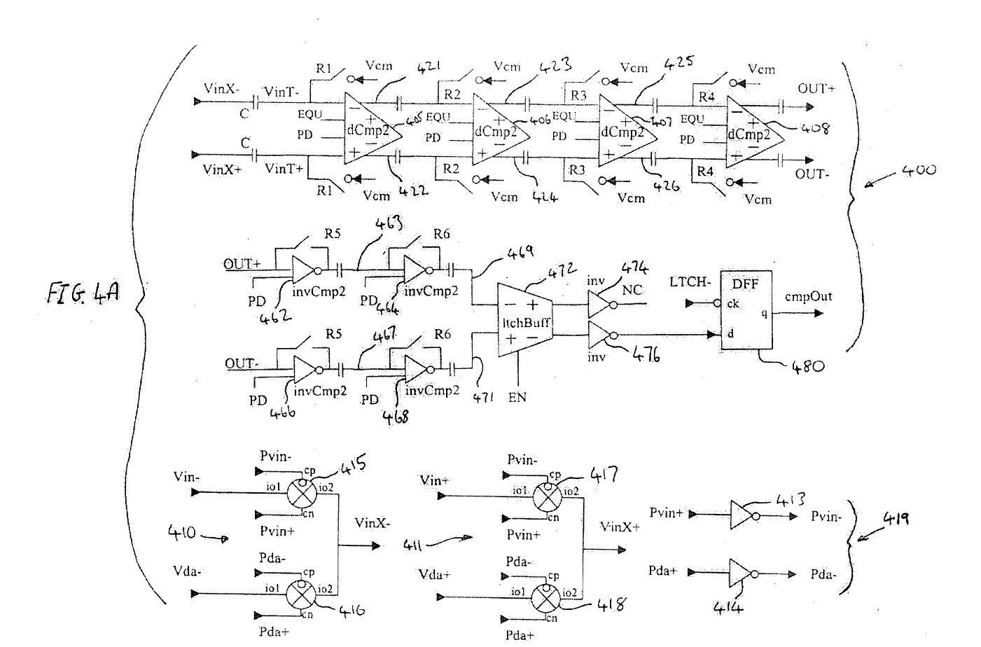

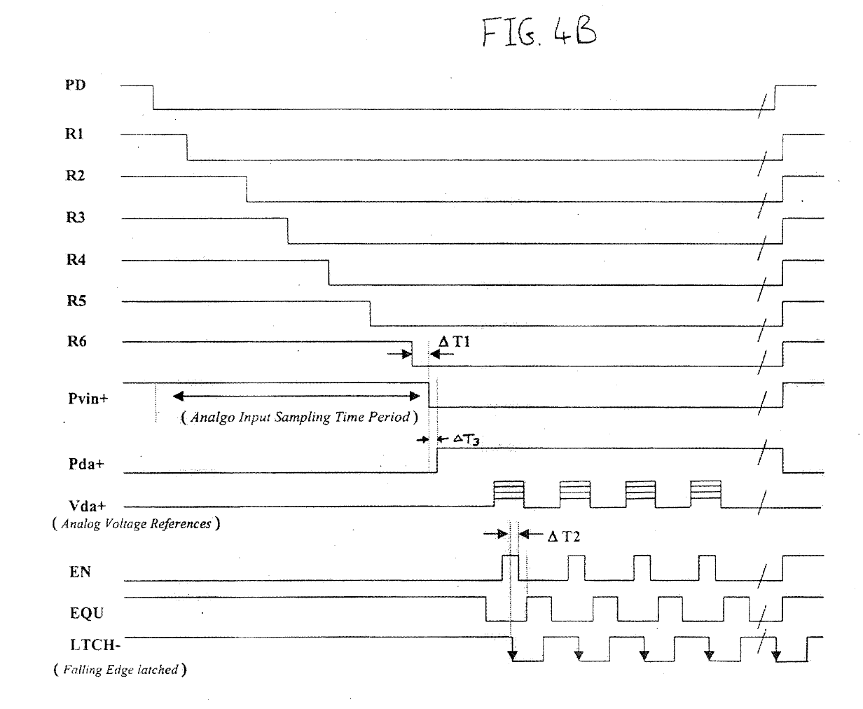

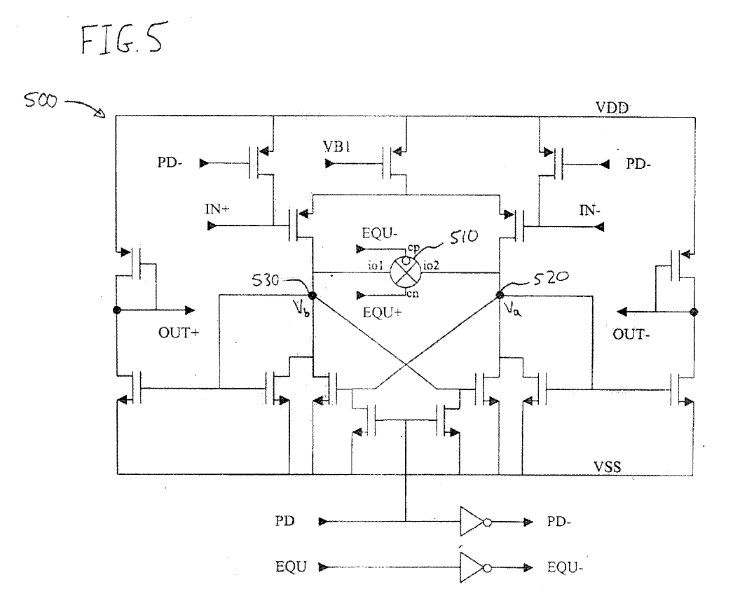

With particular reference to FIG. 4A, a schematic diagram of an embodiment of the present invention is provided, comprising, contrary to the fully-differential, single-ended (FS) structure of FIG. 1, a fully differential, single ended inverter and latched differential (FSL) structure. More specifically, the fully differential, single ended inverter and latched differential structure of FIG. 4A comprises a multistage comparator 400, which includes a combination of fully differential sub-comparators, single ended inverters and latched-differential structure for improved performance. Improved performance may be realized in for example at least one of speed (e.g., equalization devices used in, e.g., 405-408), power (e.g., power down structures used in, e.g., 405-408, 462, 464, 466, 468 and 472) and reliability (e.g., 472 being designed for extra differential gain and especially for combating unstable input transition range of a normal digital inverter). As presently embodied, multistage comparator circuit 400 comprises a plurality of fully differential sub-comparators 405, 406, 407 and 408 cascaded in series, a plurality of inverter sub-comparators 462, 464, 466 and 468, a latch type differential sub-comparator (ltchBuff) 472, a plurality of inverters 474 and 476, and a latch 480. In the illustrated embodiment, differential sub-comparators 405, 406, 407 and 408 used in multistage comparator circuit 400 are similar to differential sub-comparators 105, 106, 107 and 108 of FIG. 1A. However, each of the regenerative differential sub-comparators used in the described embodiment further comprises an equalization structure, e.g., 510 of FIG. 5, and a power down structure, e.g., 600 of FIG. 6. The power down structures 600 can also be used with inverter sub-comparators 462, 464, 466 and 468 in accordance with other aspects of the present invention. In modified embodiments, according to another aspect of the invention, the differential sub-comparators may comprise non-regenerative fully differential sub-comparators.

Differential sub-comparator 405, which is the first sub-comparator in the cascaded sub-comparators of the multistage comparator circuit 400, receives an input signal VinT−, which is the signal to be sampled, and another input signal VinT+, which is the reference signal. As previously discussed in connection with the description of FIG. 1A, VinT+=(Q+)/C+Vda+=Vcm−(Vin+−Vda+), where Q+=(Vcm−Vin+)*C and likewise VinT−=Vcm−(Vin−−Vda−). Then, the input difference is ΔV=VinT+−VinT−=−[(Vin+−Vin−)−(Vda+−Vda−)]=−(2Vin−2Vda). As this input difference is input to the FSL comparator structure in this invention, a corresponding logical high or low (the signal polarity depending on application) will be obtained at output. It is appreciated that pass circuits 410 and 411, providing Vin+, Vin−, Vda+ and Vda−, are in the illustrated embodiment similar to the pass circuits 110 and 111 used in the prior-art FIG. 1A. Differential sub-comparator 405 also receives equalization control signal EQU and power down control signal PD. Equalization control signal EQU controls the equalization structure 510 shown within an exemplary differential sub-comparator 500 in FIG. 5, and power down control signal PD controls power down devices 610 of FIG. 6. Differential sub-comparator 405 outputs two output signals 421 and 422.

Differential sub-comparator 406 receives output signal 421 and 422 from differential sub-comparator 405, equalization control signal EQU from a signal source, and power down control signal PD from another signal source. Differential sub-comparator 406 outputs two output signals 423 and 424; and differential sub-comparator 407 receives output signals 423 and 424 from differential sub-comparator 406 as well as equalization and power down control signals EQU and PD as input signals, and outputs two output signals 425 and 426. Differential sub-comparator 408 receives output signals 425 and 426 of differential sub-comparator 407 along with equalization and power down control signals EQU and PD, and provides OUT+ and OUT−.

The equalization control signal EQU, applied to differential sub-comparators 405, 406, 407 and 408 of multistage comparator circuit 400, is supplied by an equalization control signal source (not shown). Equalization structure 510 (FIG. 5), controlled by equalization control signal EQU+ and EQU−, is added to differential sub-comparator 405, 406, 407 and 408 to shorten the recovery time from opposite states (the residue states from previous comparison result) at differential sub-comparator 405, 406, 407 and 408 output nodes to their balanced/equal states.

The power down control signal PD applied to differential sub-comparators 405, 406, 407 and 408 and inverter sub-comparators 462, 464, 466 and 468 is supplied by a power down control signal source (not shown). Power-down devices, which are controlled by power down control signal PD, are designed to reduce power consumption. The power down control signal PD can help to reduce power before and after each sequence of comparison operations by ensuring that differential sub-comparators 405, 406, 407 and 408 are in power down states between comparison processes.

Inverter sub-comparators 462, 464, 466 and 468 are single-ended inverting type sub-comparators and are cascaded behind differential sub-comparators 405, 406, 407 and 408 to provide extra signal gains at a cost of occupying a relatively small silicon space. In the illustrated embodiment, inverter sub-comparators 462, 464, 466 and 468 are similar to prior-art inverter sub-comparators 162, 164, 166 and 168. However, in accordance with one aspect of the present invention each of inverter sub-comparators 162, 164, 166 and 168 is modified with the addition of a power down device, such as power down structure 600 shown in FIG. 6. Power down control signal PD controls the added power down devices of inverter sub-comparators 462, 464, 466 and 468.

Inverter sub-comparators 462 and 464 are coupled in series, wherein inverter sub-comparator 462 receives power down control signal PD and the output of differential sub-comparator 408, OUT+, as its input and provides output 463. Inverter sub-comparator 464 receives output 463 of inverter comparator 462 and power down control signal PD and provides output 469 to be used by ltchBuff 472. Similarly, inverter sub-comparators 466 and 468 are coupled in series wherein inverter sub-comparator 466 receives power down control signal PD and output of differential sub-comparator 408, OUT−, as its input and provides output 467. Inverter sub-comparator 468 receives the output 467 of inverter sub-comparator 466 and power down control signal PD and provides output 471 to be used by ItchBuff 472. The first set of inverter sub-comparators 462 and 464 and the second set of inverter sub-comparators 466 and 468 described above are coupled parallel to each other and to differential sub-comparator 408.

FIG. 4B is a schematic diagram illustrating control signals to multistage comparator circuit 400 of FIG. 4A in accordance with an embodiment of the present invention. Initially, all auto-zeroing control signals (i.e., R1, R2, R3, R4, R5, and R6) are set at “high,” thus all switches are closed and share a common voltage Vcm. Power down control signal PD is designed such that differential sub-comparators 405, 406, 407 and 408 are in power down state before and after a comparison operation. The sampling phase of the input signal Vin can be accomplished in a manner similar to that described above in the prior-art configuration, with a difference being equalization structure 510 of FIG. 5. Equalization structure 510 of FIG. 5, which is controlled by equalization control signal EQU, can shorten the recovery time from opposite states (the residue state from previous comparison result) at differential sub-comparator 405, 406, 407 and 408 output nodes to their balanced/equal states as is discussed in connection with FIG. 5.

As embodied herein, control signal Pvin and control signal Pda are non-overlapping signals. Control signal Pvin is initially, prior to the sampling phase, set at “high” state while control signal Pda is set to a “low” state for the duration of the sampling phase. Setting control signal Pvin “high” causes pass circuits 410 and 411 of FIG. 4 to deliver the analog input signals to be sampled to multistage comparator circuit 400 during the sampling phase of the comparison process. At the completion of the sampling phase and following a Δ T1 time delay, control signal Pvin is set to a “low” state; and after another time delay Δ T3 control signal Pda is set to a “high” state. It is appreciated by persons skilled in the art that each time delay mentioned is, e.g., that necessary for the setting and resetting of multistage comparator circuit 400 from one state to another state.

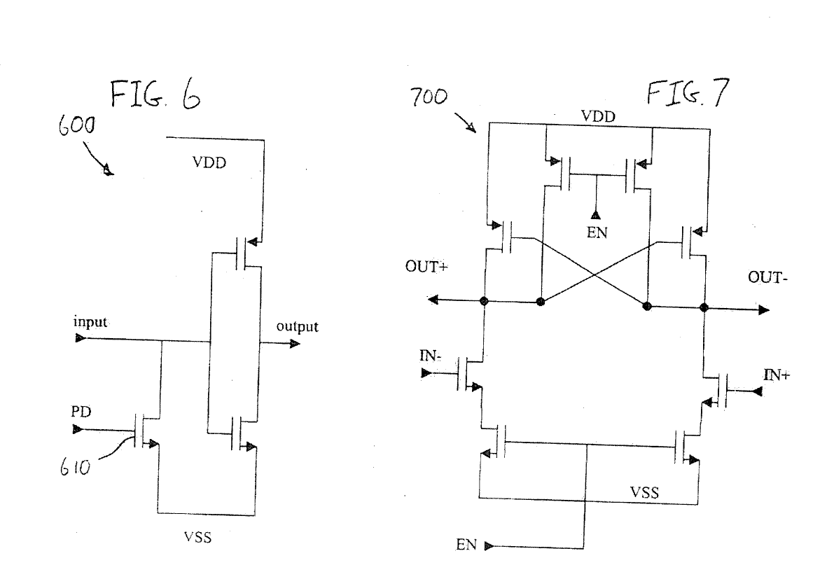

During the bit cycling phase of the comparison process, control signal Pda is constantly kept at high state so that pass circuits 410 and 411 can provide Vda, which comprises the analog voltage references, to differential sub-comparator 405. During the bit cycling phase Vda will appear as a stair like discrete waveform as depicted in FIG. 4B. When the PD control signal pulls low, the A/D conversion (consisting of two phases) occurs, and all differential- and inverter sub-comparators are kept active thus consuming DC power. While the bit cycling is in progress and comparison of the first sampled voltage is taking place, the enable EN control signal pulls high to enable the ltchBuff 472 amplifying operation. Before flip-flop DFF 480 is falling-edge triggered by latch signal LTCH, EN should stay active-high for ΔT2 time period to ensure a suitable input signal to DFF 480. After EN pulls low, EQ signal will facilitate equalization of voltages Va and Vb on nodes A and B of FIG. 5. The EN control signal shown in FIG. 4B is used to enable ItchBuff 472 (FIG. 4A and 700 of FIG. 7), so that when EN is high ltch-Buff 472 will be active and an amplified output pair (OUT+ and OUT−) will respond to input signal (IN− and IN+). As presently embodied, ItchBuff 472 comprises an internal power down structure, and the inversion of EN (FIGS. 4B and 7) operates as a power down signal. When at low, EN will disable (turn off) the bottom two NMOSs (in FIG. 7), thus cutting-off current paths between VDD and VSS. At the same time, when at low, EN will turn on the top two PMOSs (in FIG. 7), thus setting both output nodes (OUT+ and OUT−, in FIG. 7) at VDD such that a logical high appears at both inverters 474 and 476 (FIG. 4A) and causes no leakage path on them.

For reducing power consumption, EN can be set low when the appropriate input signal pair is not available at input (IN+ and IN−). This power reduction concern is elucidated in FIG. 4B, wherein when Pvin+=low and Pda+=high, the appearing time of each rising edge of EN is set to be later than that of the analog voltage reference Vda+. The pulse-width design of EN will consider the total response time of ltchBuff 472, the inverter stage 476 (FIG. 4A) and the flip-flop DFF 480 (FIG. 4A). Consequently, at the falling edge of LTCH−, well-developed output signals will be ensured at both ltchBuff 472 and inverter 476, and an unambiguous comparison result can be latched at the output of DFF 480.

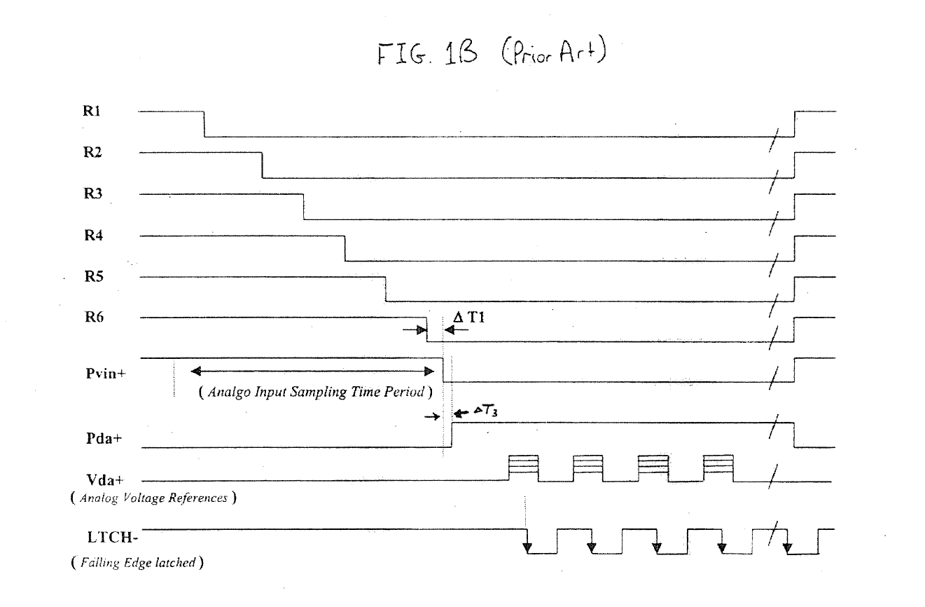

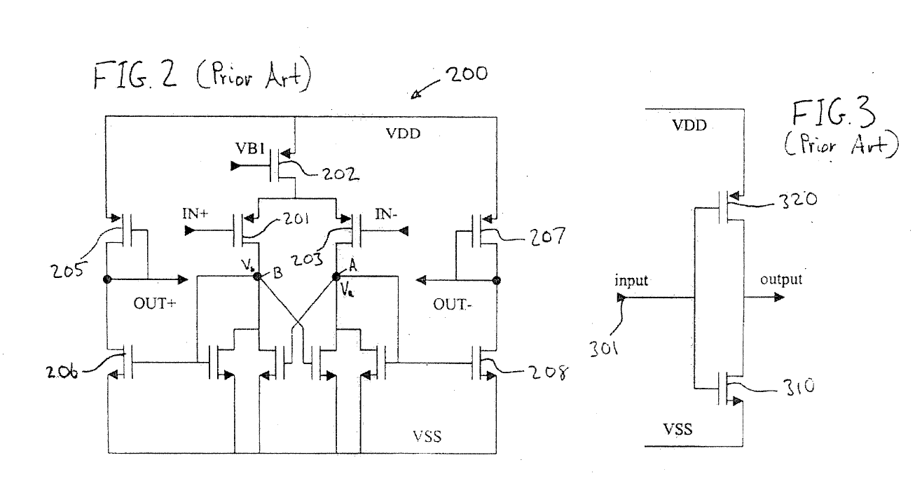

FIG. 5 is a schematic diagram of a fully differential sub-comparator, which in the illustrated embodiment is similar to differential sub-comparator 200 of FIG. 2, except, e.g., for the addition of an equalization structure 510. Equalization device 510 is controlled by equalization control signal EQU of FIG. 4B. Furthermore, the present invention provides power down control signals PD to, e.g., the differential sub-comparator 500 in accordance with the timing shown in FIG. 4B.

According to one embodiment of the present invention, equalization control signal EQU and power down control signal PD are applied to differential sub-comparators 405, 406, 407 and 408 while, e.g., multistage comparator circuit 400 is in the bit cycling phase. Equalization control signal EQU is applied to equalization structure 510, which operates to cause voltages Va at node 520 and voltage Vb at node 530 to equalize and thus speed up the process of the next comparison phase. Power down control signal PD controls a load circuit in accordance with an embodiment of the present invention. Power down control signal PD is applied to differential sub-comparators 405, 406, 407 and 408, and inverter sub-comparators 462, 464, 466 and 468, to help reduce power consumption. Power down control signal PD is applied to differential sub-comparators 405, 406, 407 and 408 to power down the sub-comparators before and after a sequence of conversion as discussed previously.

FIG. 6 is a schematic diagram illustrating a single-ended inverting type sub-comparator 600, corresponding to for example one of the inverter sub-comparators 462 and 464 cascaded in series behind the last differential sub-comparator 408 in the cascaded differential sub-comparators 405, 406, 407 and 408. In the illustrated embodiment, inverting type sub-comparator 600 is basically the same as inverter sub-comparator 200 of FIG. 2 except inverting type sub-comparator 600 further includes a power down device 610, which is controlled by power down control signal PD. Application of power down control signal PD+ to power down device 610 can attenuate or eliminate leakage current present in prior art inverter sub-comparator 200 of FIG. 2 by grounding input when power down control signal PD is “high,” resulting in turning transistor 610 “on.” According to one embodiment of the present invention, the addition of power down device can result in reduction or stoppage of current leakage while the gain intended by addition of the inverter sub-comparator is still available.

FIG. 7 is a schematic diagram illustrating a latch type differential sub-comparator 700, corresponding to for example ltchBuff 472 of FIG. 4A, with enable control signal and which possesses a simple self-biased design. Latch type differential sub-comparator 700 is added to multistage comparator circuit 400, as ltchBuff 472, to eliminate a possibility of unstable operation, which may be experienced in high precision applications, e.g., a small analog input signal, and where the input level resides in the unstable regions of the digital inverter structure. When implemented in VLSI technology, the physical placement of both differential sub-comparator 405, 406, 407 and 408 and inverter sub-comparator 462, 464, 466 and 468 blocks can be relatively close to one another, so that nearly the same common-mode level is assumed and in effect only the differential signals are amplified and latched at output. Since ItchBuff 472 of FIG. 4A, which receives output signals 469 and 471 from inverter sub-comparators 464 and 468, respectively, can provide extra gain and more reliable output than prior-art architectures, addition of ItchBuff 472 can be a prudent design consideration with the enabled period for LtchBuff 472 occupying only a small fraction of the whole active conversion time, as shown in FIG. 4B.

In view of the foregoing, it will be understood by those skilled in the art that the present invention provides a method and a circuit which can combat environmental noise, cancel input DC offset voltage in an AID converter and reduce power consumption while providing a reliable voltage. The above-described embodiments have been provided by way of example, and the present invention is not limited to these examples. Multiple variations and modification to the disclosed embodiments will occur, to the extent not mutually exclusive, to those skilled in the art upon consideration of the foregoing description. Additionally, other combinations, omissions, substitutions and modifications will be apparent to the skilled artisan in view of the disclosure herein. Accordingly, the present invention is not intended to be limited by the disclosed embodiments, but is to be defined by reference to the appended claims.

What is claimed is:

1. A comparator circuit for comparing a first and a second input signal, the comparator circuit comprising:
a plurality of fully differential sub-comparators cascaded in series;
a plurality of inverter sub-comparators coupled to the plurality of fully differential sub-comparators;
a plurality of inverters coupled to the plurality of inverter sub-comparators ; and
a plurality of power-down control signal lines coupled to at least one of the plurality of fully differential sub-comparators and the plurality of inverter sub-comparators.

2. The comparator circuit for comparing a first and a second input signal as set forth in claim 1, wherein:
the comparator circuit further comprises a latch type differential sub-comparator coupled to the plurality of inverter sub-comparators, and
the plurality of inverters are coupled to the plurality of inverter sub-comparators
via the latch type differential sub-comparator.

3. The comparator circuit for comparing a first and a second input signal as set forth in claim 2, and further comprising a plurality of equalization control signal lines coupled to the plurality of fully differential sub-comparators.

4. The comparator circuit for comparing a first and a second input signal as set forth in claim 1, and further comprising a plurality of equalization control signal lines coupled to the plurality of fully differential sub-comparators.

5. The comparator circuit for comparing a first and a second input signal as set forth in claim 4, wherein the plurality of power-down control signal lines is coupled to the plurality of fully differential sub-comparators and the plurality of inverter sub-comparators.

6. The comparator circuit for comparing a first and a second input signal as set forth in claim 4, and further comprising a power down control signal source and an equalization control signal source.

7. The comparator circuit for comparing a first and a second input signal as set forth in claim 1, wherein the comparator circuit includes four fully differential sub-comparators cascaded in series.

8. The comparator circuit for comparing a first and a second input signal as set forth in claim 1, wherein the fully differential sub-comparators are non-regenerative type sub-comparators.

9. The comparator circuit for comparing a first and a second input signal as set forth in claim 8, wherein the comparator circuit includes two-inverter sub-comparators.

10. The comparator circuit for comparing a first and a second input signal as set forth in claim 4, wherein at least one of the equalization control signal lines operates to cancel an offset voltage in at least one of the fully differential sub-comparators.

11. The comparator circuit for comparing a first and a second input signal as set forth in claim 10, wherein a power down control signal changes a state of at least one of the fully-differential sub-comparators, via at least one of the power-down control signal lines, prior to a bit cycling phase.

12. The comparator circuit for comparing a first and a second input signal as set forth in claim 1, wherein a power down control signal eliminates leakage, via at least one of the power-down control signal lines, in at least one of the inverter sub-comparators.

13. The comparator circuit for comparing a first and a second input signal as set forth in claim 4, wherein at least one of the equalizing control signal lines operates to control a load circuit within the comparator circuit.

14. A comparator circuit for comparing a first and a second input signal, the comparator circuit comprising:
a plurality of fully differential sub-comparators cascaded in series;
a plurality of inverter sub-comparators coupled to the plurality of fully differential sub-comparators; and
a latch type differential sub-comparator coupled to the plurality of inverter sub-comparators.

15. The comparator circuit for comparing a first and a second input signal as set forth in claim 14, and further comprising:
a plurality of inverters coupled to the latch type differential sub-comparator; and
a latch coupled to the plurality of inverters.

16. The comparator circuit for comparing a first and a second input signal as set forth in claim 14, and further comprising a plurality of power-down control signal lines coupled to at least one of the plurality of fully differential sub-comparators and the plurality of inverter sub-comparators.

17. The comparator circuit for comparing a first and a second input signal as set forth in claim 16, wherein the plurality of power-down control signal lines is coupled to the plurality of fully differential sub-comparators and the plurality of inverter sub-comparators.

18. The comparator circuit for comparing a first and a second input signal as set forth in claim 17, and further comprising a plurality of equalization control signal lines coupled to the plurality of fully differential sub-comparators.

19. The comparator circuit for comparing a first and a second input signal as set forth in claim 16, and further comprising:
a plurality of equalization control signal lines coupled to the plurality of fully differential sub-comparators; and
a power down control signal source and an equalization control signal source.

20. A method of using a comparator to perform comparison of input signals, the method comprising:
sampling an input signal and holding the sampled input signal for comparison with a voltage reference signal;
applying an equalization control signal to equalize an offset voltage within the comparator;
applying a power down control signal to attenuate or remove power to at least one component of the comparator during a time between a sampling phase and a comparison phase; and
providing a latch to maintain an output voltage at a triggering of the latch.

21. The method for comparing input signals as set forth in claim 20, wherein the equalization control signal is in a high state during the sampling phase.

22. The method for comparing input signals as set forth in claim 20, wherein the equalization control signal changes to a low state during at least part of the comparison phase.

23. The method for comparing input signals as set forth in claim 20, wherein an enable control signal for the latch shifts high to enable the latch and inverts to a low state after a predetermined delay has occurred following the triggering of the latch, the inversion of the enable control signal facilitating a powering-down of the latch.

24. The method for comparing input signals as set forth in claim 20, wherein the power down control signal shifts to a predetermined state to turn off operation of at least part of the comparator and thereby effectuate energy conservation.

25. The method for comparing input signals as set forth in claim 20, wherein the latch comprises a falling-edge triggered latch that remains in a high state during the sampling phase.

26. The method for comparing input signals as set forth in claim 20, wherein an enable control signal for the latch is in a low state during the sampling phase serving to hold the latch in a power-down mode, the enable control signal shifting to a high state to enable the latch before triggering of the latch and shifting back to a low state, powering-down the latch once again, following a predetermined delay after triggering of the latch.

27. The method for comparing input signals as set forth in claim 26, wherein the power down control signal turns off at least part of the comparator between the sampling and bit cycling phases.

28. The method for comparing input signals as set forth in claim 20, wherein the power down control signal serves to attenuate or eliminate a leakage current within the comparator.
